(19) United States
(12) Patent Application Publication
(10) Pub. No.: US 2003/0124762 A1
(43) Pub. Date: Jul. 3, 2003

(54) Optical device and method of manufacturing the same, optical module, circuit board, and electronic instrument

(76) Inventor: Nobuaki Hashimoto, Suwa-shi (JP)

Correspondence Address: HOGAN & HARTSON L.L.P., 500 S. GRAND AVENUE, SUITE 1900, LOS ANGELES, CA, 90071-2611, US

(21) Appl. No.: 10/290,062

(22) Filed: Nov. 6, 2002

(30) Foreign Application Priority Data
Dec. 27, 2001 (JP) 2001-397050

(51) Int. Cl. H01L 21/00; B29D 11/00; G02B 1/12

(52) U.S. Cl. 438/67; 264/1.36; 264/2.7

(57) ABSTRACT

An optically transmitting first substrate and a second substrate are opposed with spacers interposed therebetween, the second substrate including a plurality of optical elements, each of the optical elements having an optical section, each of the spacers surrounding each of the optical sections. Each of the optical sections is sealed by connecting the first substrate and the second substrate with the spacer interposed. The second substrate is separated into individual one of the optical elements, the individual one of the optical elements including one of the sealed optical sections.

Japanese Patent Application No. 2001-397050, filed on Dec. 27, 2001, is hereby incorporated by reference in its entirety.

### BACKGROUND OF THE INVENTION

The present invention relates to an optical device and method of manufacturing the same, to an optical module, and to a circuit board and an electronic instrument.

In an optical element having an optical section such as a photoreceptor or the like, it is known to be preferable to provide a space between the surface bearing the optical section and a cover for sealing. For this purpose, the method of manufacturing an optical device is known in which, after the optical elements are cut apart and diced, the optical section is sealed by a cover, with a space provided between the optical section and the cover. When cutting a substrate such as a wafer or the like by dicing or similar method, swarf and the like are generated. If dust such as this swarf or the like is in contact with the optical section when it is sealed, it is not possible thereafter to remove the dust from this space, and there is the problem that the quality of the optical device is reduced. In particular, in the case of a solid state imaging device having an optical section with a microlens, since the microlens has a relief surface, dust attaches easily, and complete removal is difficult. Therefore, in the case that there is an optical section with a microlens, there is the problem that the quality of the solid state imaging device tends to be even further reduced.

### BRIEF SUMMARY OF THE INVENTION

A method of manufacturing an optical device according to an aspect of the present invention comprises:

(a) opposing an optically transmitting first substrate to a second substrate with spacers interposed therebetween, the second substrate including a plurality of optical elements, each of the optical elements having an optical section, each of the spacers surrounding each of the optical sections;

(b) sealing each of the optical sections by the first substrate and the spacers by connecting the first substrate and the second substrate with the spacer interposed; and

(c) separating the second substrate into individual one of the optical elements, the individual one of the optical elements including one of the sealed optical sections.

An optical device according to another aspect of the present invention is manufactured by the above method.

An optical module according to a further aspect of the present invention has the above described optical device,

and a supporting member to which the optical device is attached.

A circuit board according to a still further aspect of the present invention has the above described optical module mounted on the circuit board.

An electronic instrument according to a yet further aspect of the present invention has the above described optical module.

### BRIEF DESCRIPTION OF THE SEVERAL VIEWS OF THE DRAWING

FIGS. 1A to 1C illustrate a first embodiment of the method of manufacturing an optical device according to the present invention;

FIG. 2 illustrates the first embodiment of the method of manufacturing an optical device according to the present invention;

FIG. 3 illustrates the first embodiment of the method of manufacturing an optical device according to the present invention;

FIGS. 4A to 4C illustrate the first embodiment of the method of manufacturing an optical device according to the present invention;

FIGS. 5A and 5B illustrate a first embodiment of the optical device according to the present invention;

FIGS. 6A and 6B illustrate a second embodiment of the method of manufacturing an optical device according to the present invention;

FIGS. 7A to 7E illustrate a third embodiment of the method of manufacturing an optical device according to the present invention;

FIG. 8 illustrates a fourth embodiment of an optical module and circuit board according to the present invention;

FIG. 9 shows an embodiment of an optical module according to the present invention;

FIG. 10 shows an embodiment of an optical module according to the present invention;

FIG. 11 shows an embodiment of an electronic instrument according to the present invention;

FIG. 12 shows an embodiment of an electronic instrument according to the present invention; and

FIGS. 13A and 13B show embodiments of an electronic instrument according to the present invention.

### DETAILED DESCRIPTION OF THE EMBODIMENT

Embodiments of the present invention may provide a high quality optical device and method of manufacturing the same, optical module, circuit board, and electronic instrument.

(1) A method of manufacturing an optical device of the present invention comprises:

(a) opposing an optically transmitting first substrate to a second substrate with spacers interposed therebetween, the second substrate including a plurality of optical elements, each of the optical elements having an optical section, each of the spacers surrounding each of the optical sections;

(b) sealing each of the optical sections by the first substrate and the spacers by connecting the first substrate and the second substrate with the spacer interposed; and

(c) separating the second substrate into individual one of the optical elements, the individual one of the optical elements including one of the sealed optical sections.

According to the embodiment of the present invention, after the optical section of the second substrate is sealed, the second substrate is separated, and therefore it is less likely for dust and the like to adhere to the optical section. By means of this, the ingress of dust to the sealed part can be reduced, and a high quality optical device can be obtained.

(2) In this method of manufacturing an optical device,

in the step (c), the first substrate may be separated, and

the first substrate may be separated with a first cutter, and the second substrate may be separated with a second cutter.

(3) In this method of manufacturing an optical device,

a width of the first cutter may be greater than a width of the second cutter.

According to this, the width of the separation region of the first substrate is greater than the width of the separation region of the second substrate.

(4) In this method of manufacturing an optical device,

each of the optical elements may have electrodes outside of the optical section, and

in the step (c), a part of the first substrate over the electrodes may be removed when the first substrate is separated.

According to this, since the space above the electrodes on the first substrate is left free, carrying out electrical connection to the electrodes is made easier.

(5) In this method of manufacturing an optical device,

the first substrate may have a groove formed along a separation line, and

in the step (c), the first substrate may be separated in a region in which the groove is formed.

According to this, when the portion of the first substrate in which the groove is formed is separated, since the thickness of this portion is less than that of other portions, the second substrate can be made less likely to be damaged. The separation position of the first substrate can be made clear. Compared with separating a portion not having a groove formed, the first substrate can be separated without the extremity of the first cutter approaching the second substrate.

(6) In this method of manufacturing an optical device,

in the step (a), the spacers may be formed on one of the first and second substrates, and

in the step (b), the spacers may be attached to the other one of the first and second substrates.

(7) In this method of manufacturing an optical device,

each of the spacers may have a thermosetting resin, and

the first substrate and the second substrate may be connected by heating the spacers in the step (b).

(8) In this method of manufacturing an optical device,

each of the spacers may have a light curable resin, and

the first substrate and the second substrate may be connected by irradiating the spacers with light in the step (b).

(9) In this method of manufacturing an optical device,

the thermosetting resin may be provisionally cured before the step (b).

(10) In this method of manufacturing an optical device,

the light curable resin may be provisionally cured before the step (b).

(11) In this method of manufacturing an optical device,

the spacers may be formed of metal, and

in the step (b), soldering or brazing may be carried out.

(12) In this method of manufacturing an optical device,

a solder or a brazing alloy may be provided on one of the first and second substrates to which the spacers are to be attached, before carrying out the soldering or brazing.

(13) In this method of manufacturing an optical device,

in the step (b), the optical section may be sealed so as to form a space between the first substrate and the optical section.

(14) In this method of manufacturing an optical device,

in the step (b), the optical section may be sealed so that the space is vaccumized.

(15) In this method of manufacturing an optical device,

in the step (b), the optical section may be sealed so that the space is filled with nitrogen.

(16) In this method of manufacturing an optical device,

in the step (b), the optical section may be sealed so that the space is filled with dry air.

(17) In this method of manufacturing an optical device,

the first substrate may transmit visible light, and may not transmit infrared radiation.

(18) In this method of manufacturing an optical device,

the second substrate may be a semiconductor wafer.

(19) In this method of manufacturing an optical device,

each of the optical sections may have a plurality of photoreceptors arranged for image sensing.

(20) In this method of manufacturing an optical device,

each of the optical sections may have a color filter provided over the photoreceptor.

(21) In this method of manufacturing an optical device,

each of the optical sections may have a microlens array provided on the surface of the second substrate.

(22) An optical device according to another embodiment of the present invention is manufactured by the above method.

(23) An optical module according to a further embodiment of the present invention has the above described optical device; and

a supporting member to which the optical device is attached.

(24) A circuit board according to a still further embodiment of the present invention has the above described optical module mounted on the circuit board.

(25) An electronic instrument according to a yet further embodiment of the present invention has the above described optical module.

These embodiments of the present invention are now described with reference to the drawings.

First Embodiment

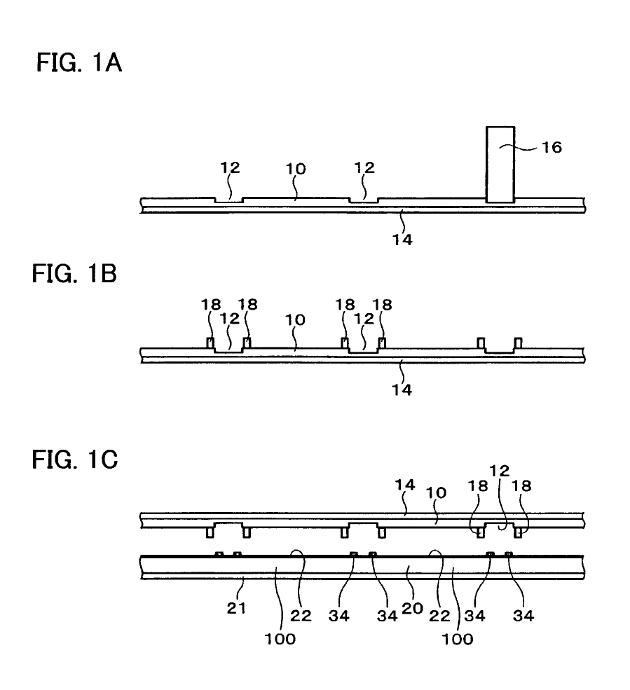

FIG. 1A to FIG. 5B illustrate the optical device and method of manufacturing a first embodiment of the present invention. In this embodiment, first and second substrates 10 and 20 are used.

As shown in FIG. 1A, a first substrate 10 is prepared. The size and shape of the first substrate 10 is not particularly restricted, but is preferably of the same size as the second substrate 20, and even more preferably of the same shape as the second substrate 20. Further, for example, as shown in FIG. 3, it may be a quadrilateral. The first substrate 10 has light transmitting property. As the first substrate 10 optical glass can be used. As long as the first substrate 10 permits light to pass, the magnitude of light losses is not an issue, and it is sufficient if light of particular wavelengths only is passed. For example, the first substrate 10 may transmit visible light, but not transmit light in the infrared range. The first substrate 10 may have low losses in the visible light range, but high losses in the infrared range. Further, on the surface of the first substrate 10, antireflection film, infrared shielding film, or a film of similar optical functionality may be formed. In this way, since it is not necessary to provide a separate member from the substrate having such optical functionality, the optical device or the like can be made even more compact.

As shown in FIG. 1A, in the first substrate 10, a groove 12 may be provided. When the groove 12 is formed by cutting the first substrate 10, applying a protective material such as a sheet 14 or the like to the first substrate 10 increases the workability, and allows cracks in the first substrate 10 to be prevented. The groove 12 may be formed by half-cutting the first substrate 10. By “half-cutting” is meant not completely cutting the first substrate 10, but by cutting as shown in FIG. 1A providing a groove. In this case, the formation of the groove 12 can be carried out by dicing using a dicing blade 16. The groove 12 is formed on the separation line of the first substrate 10. For example, as shown in FIG. 3, a plurality of the grooves 12 may be formed, in the form of a lattice. As a modification, the first substrate 10 need not have the groove 12. As a further modification, the first substrate 10 may be a transparent substrate already diced, and a plurality of the transparent substrates may be supported on a protective material such as the sheet 14 or the like.

Next, the first and second substrates 10 and 20 are attached together, with at least one spacer 18 interposed. A plurality of the spacers 18 may be provided. For example, a spacer 18 is formed on one of the first and second substrates 10 and 20, and the spacer 18 is attached to the other of the first and second substrates 10 and 20. As an example, as shown in FIG. 1B, on the first substrate 10 is provided a spacer 18 in the form of a frame. Each spacer 18 is provided on a part of the first substrate 10 which will form a transparent substrate 110 by cutting. In the example shown in FIG. 1B, each spacer 18 is provided on a portion surrounded by the groove 12 (see FIG. 3). Each spacer 18 may be formed so as to be continuous with its neighbors (that is, with no division). In this case, the attachment of the spacer 18 is made easier. Each spacer 18 is formed so as to surround an optical section 22 described below.

In this embodiment, the spacer 18 is formed of resin. When the adhesion of the first and second substrates 10 and 20 is considered, thermoplastic resin, light curable resin, thermosetting resin, or a resin being a combination thereof or the like may be used. For example, a layer of a photosensitive resin (a photoresist or the like, being a photosensitive polyimide or the like) may be provided on the first substrate 10, and photolithography applied, so that by patterning thereof the spacer 18 is formed. Alternatively, the spacer 18 may be formed by screen printing. It should be noted that when the spacer 18 is formed of light curable resin or thermosetting resin, deformation thereof can be limited by provisional curing. If the resin of which the above described spacer 18 is formed is a resin cured by ultraviolet radiation, for the provisional curing, irradiation by weak ultraviolet radiation can be applied. Here, “provisional curing” refers to a state in which the resin is not completely cured, but the resin subjected to provisional curing has plasticity lower than the plasticity of the resin at room temperature. By means of this, when the first and second substrates 10 and 20 are attached together with the spacer 18 interposed, since the resin is not liable to deformation, it is possible to reduce the liability of the resin to stick to the below described optical section 22. Therefore, interference with the passage of light into or out of the optical section as a result of adhering resin can be prevented. The spacer 18 may be a material such that at least the surface is insulating.

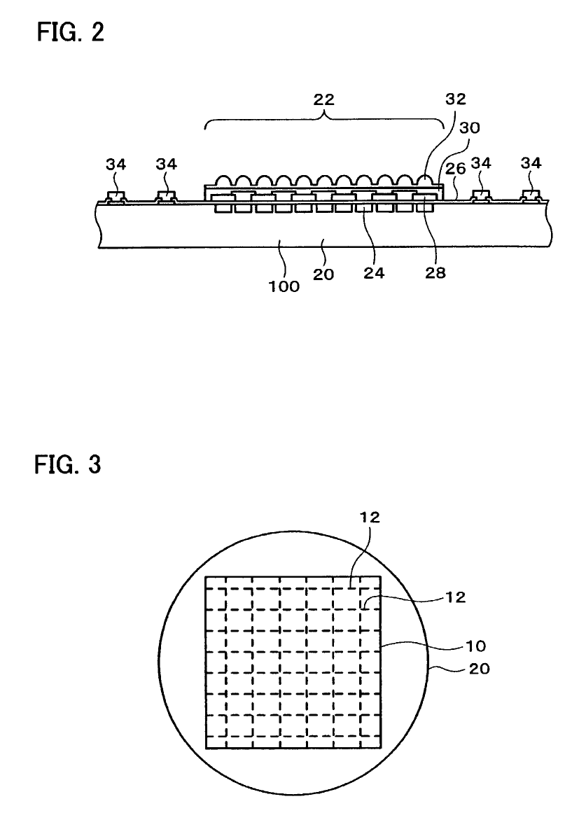

As shown in FIG. 1C, the second substrate 20 is prepared. To the second substrate 20 may be applied a sheet 21 for the purpose of improving the workability in a cutting process described below. FIG. 2 is an enlarged view of part of the second substrate 20. The second substrate 20 has a plurality of optical elements 100 including optical sections 22. The optical element 100 includes the optical section 22 and electrodes 34. The optical section 22 may have a part which receives or emits light (photoreceptor or photoemitter), and may have parts which convert light energy to other forms of energy (for example, electrical energy) or convert other forms of energy (for example, electrical energy) to light energy. A single optical section 22 may have a plurality of energy transducers (photoreceptors or photoemitters) 24.

In this embodiment, the description is of a solid state imaging device (for example, image sensors such as a CCD, in particular a CCD equipped with photodiodes, and CMOS sensors) as an example. In this case, each optical section 22 has a plurality of energy transducers (photoreceptors or image sensors or the like) 24. As shown in FIG. 2, the plurality of energy transducers 24 is disposed in two dimensions, so as to be able to carry out image sensing. The energy transducer 24 may be covered by an optically transmitting passivation film 26. If the second substrate 20 includes a semiconductor substrate (for example, a semiconductor wafer or the like), the passivation film 26 may be formed of SiO₂ or SiN.

The optical section 22 may have a color filter 28. The color filter 28 may be formed over the passivation film 26. A leveling layer 30 may be provided over the color filter 28. On the surface of the optical section 22, a microlens array 32 may be provided. In this case, the first substrate 10 and spacer 18 are sealed at least in the region of the second substrate 20 in which the microlens array 32 is provided.

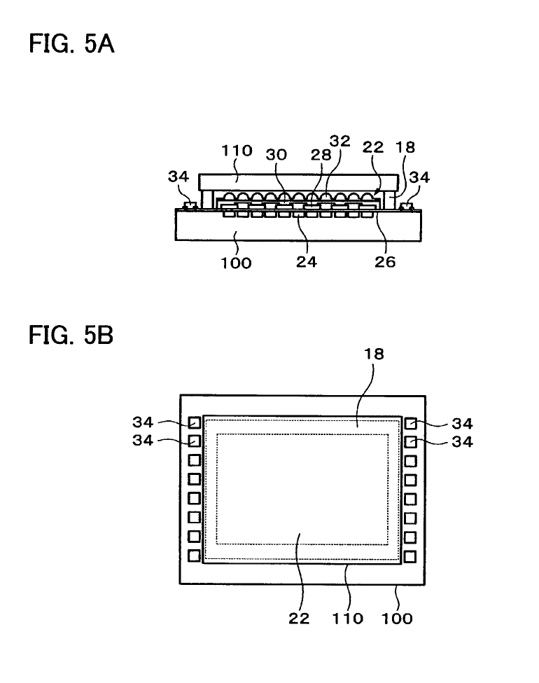

On the second substrate 20 a plurality of electrodes 34 is formed. The electrodes 34 shown in FIG. 2 have bumps formed on pads, but may be pads only. As shown in FIG. 2, it is preferable for the electrodes 34 to be formed on the outside of the optical section 22 in an individual optical element 100. For example, the electrodes 34 may be formed between adjacent optical sections 22. A single optical section 22 corresponds to a group of electrodes 34. For example, as shown in FIG. 5B, the electrodes 34 may be disposed along a plurality of sides (for example, two opposing sides) of the optical section 22. The electrodes 34 may be disposed along one side of the optical section 22.

As shown in FIG. 1C, the first and second substrates 10 and 20 are opposed. In more detail, the surface of the second substrate 20 on which the optical section 22 is formed, and the first substrate 10 are opposed. FIG. 3 is a plan view showing the opposing first and second substrates. When the first substrate 10 has the groove 12, the surface having the groove may be disposed to oppose the second substrate 20. When a protective material such as the sheet 14 or the like is provided on the separated first substrate 10, the surface opposite to the surface on which the protective material is provided may be disposed to oppose the second substrate. At this point, the spacer 18 is disposed between the first and second substrates 10 and 20. The spacer 18 is disposed to surround the optical section 22 of the second substrate 20 (see FIG. 5B).

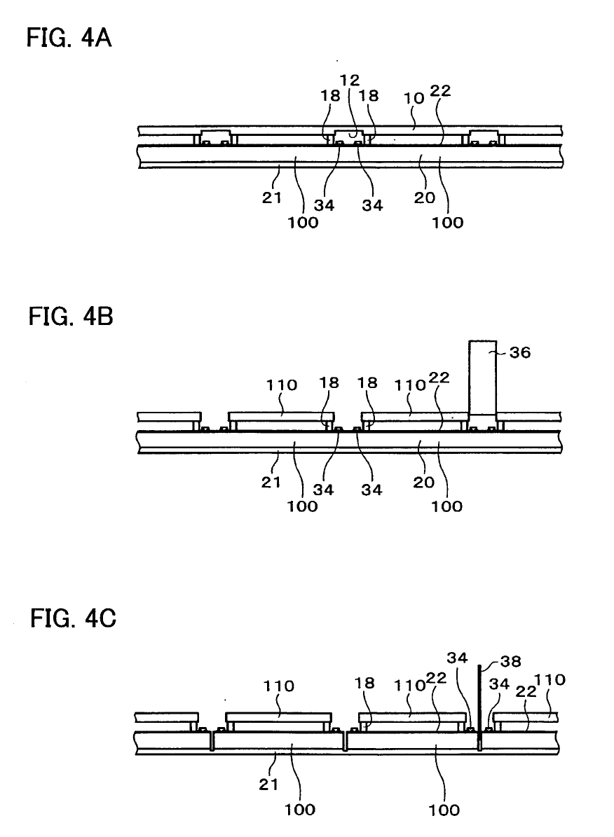

As shown in FIG. 4A, the first and second substrates 10 and 20 are attached together with the spacer 18 interposed. For example, when the spacer 18 is formed of a thermosetting resin, the spacer 18 provided on the first substrate 10 and the second substrate 20 are contacted, and the spacer 18 is heated to activate its adhesion force. Alternatively, an adhesive may be provided between the second substrate and the spacer 18. In this way, the optical section 22 can be sealed by the first substrate 10 and spacer 18. In this embodiment, the optical section 22 is sealed so as to form a space between the first and second substrates 10 and 20. Here, the space may be at less than atmospheric pressure, or may be vaccumized, or may be filled with nitrogen or dry air or the like. For example, the above described construction may be obtained by a sealing process carried out at a pressure less than atmospheric pressure, in a vacuum, or in an atmosphere of nitrogen or dry air or the like. By means of this, water vapor or the like within the space can be reduced, and condensation in the product such as the semiconductor device or electronic component, or rupture caused by an increase of the pressure within the space in a heating process can be prevented. It should be noted that if necessary, the sheet 14 applied to the first substrate 10 is peeled off. Further, immediately before this sealing process, it is preferable for washing and drying and so forth of the first and second substrates 10 and 20 to be carried out. This is so that by carrying out purification of the optical section 22 immediately before sealing, dust or the like within the space can be avoided, and the final product yield can be further improved.

As shown in FIG. 4B, the first substrate 10 is separated into transparent substrates 110. This separation is carried out to avoid the part of the first substrate 10 which forms the transparent substrates 110. That is to say, the first substrate 10 is separated outside the region surrounded by the spacer 18 (where the optical section 22 is positioned) and the spacer 18, or so as to leave at least a part of the spacer 18. In this embodiment, the first substrate 10 is separated along the groove 12.

The separation line of the first substrate 10 is positioned over the electrodes 34 on the second substrate 20. To make it easier to carry out electrical connection to the electrodes 34 in a subsequent process, the part of the first substrate 10 above the electrodes 34 is removed. For example, as a first cutter 36 for separating the first substrate 10 is used a tool which cuts and separates. In this way, the space above the electrodes 34 is opened. It should be noted that it is preferable for the first cutter 36 (for example, a dicing blade) used to have a separation width larger than that of a second cutter 38 described below.

In the example shown in FIG. 4B, the groove 12 is formed by the first cutter 36. This is to reduce the likelihood of damage to the second substrate 20 in the cutting process, and also allows the separation position of the first substrate 10 to be clearly shown. In this embodiment, the state shown is of the groove 12 provided, but equally, without providing the, groove 12, the first substrate 10 may be directly separated by the first cutter 36. The width of the first cutter 36 is substantially equal to the width of the groove 12. Here, by “substantially equal” is included the case of total equality and the case of equality bearing in mind a minor difference. Alternatively, the width of the first cutter 36 may be less than the width of the groove 12. In this case, since the first substrate 10 is separated within the groove 12, a step is created on the end portion of the transparent substrate 110. Alternatively, the width of the first cutter 36 may be larger than the width of the groove 12. Further, the width of the first cutter 36 may be greater than the interval between adjacent spacers 18. In this case, as the first substrate 10 is separated, a part of the spacer 18 is cut away.

The separation of the first substrate 10 is carried out so as not to damage the electrodes 34 or second substrate 20, and particularly the surface of the second substrate 20. In this embodiment, the surface of the first substrate 10 in which the groove 12 is formed opposes the electrodes 34. As a result, since the surface of the first substrate 10 is apart from the electrodes 34 by the depth of the groove 12, the edge of the first cutter 36 is less likely to come in contact with the electrodes 34.

As shown in FIG. 4C, the second substrate 20 is separated into individual optical elements 100. The second cutter 38 (for example, dicing blade) used for this separation may have a lesser width than that of the first cutter 36. The second substrate 20 is separated on the outside of the optical section 22, and further on the outside of the electrodes 34. In the example shown in FIG. 4C, between adjacent optical sections 22 are formed electrodes 34 corresponding to the respective optical sections 22, and the second substrate 20 is separated between these electrodes 34. If the sheet 21 is applied to the second substrate 20, even when the second substrate 20 is separated into individual optical elements 100, the optical elements 100 are still held together. In this way, an optical device sealed by the transparent substrate 110 and spacer 18 is obtained. According to this embodiment, since the second substrate 20 is separated after sealing the optical sections 22, no dust enters the sealed part, and a high quality optical device can be obtained.

FIGS. 5A and 5B illustrate a first embodiment of the optical device according to the present invention. The optical device includes the transparent substrate 110, optical element 100, and spacer 18. Light enters the optical section 22 from the transparent substrate 110. The optical section 22 provided in the optical element 100 is sealed by the transparent substrate 110 and the spacer 18. Between the optical section 22 and the transparent substrate 110 a space is formed. This space may be vaccumized, or may be filled with nitrogen or dry air. In this way, condensation does not occur in the optical section 22. The optical element 100 is provided with electrodes 34 outside the optical section 22, and further outside the members sealing the optical section 22 (the transparent substrate 110 and spacer 18). Other details are as described in the above described method of manufacturing an optical device.

The present invention is not restricted to the above described embodiment, and various modifications are possible. For example, the present invention includes substantially the same construction as the construction described in the embodiment (for example, a construction for which the function, method, and result are the same, or a construction of which the purpose and result are the same). The present invention includes a construction in which parts which are not of the essence of the construction described in the embodiment are replaced. The present invention includes a construction having the same effect as the construction described in the embodiment or a construction capable of achieving the same purpose. The present invention includes a construction having the construction described in the embodiment to which is added well-known art.

Second Embodiment

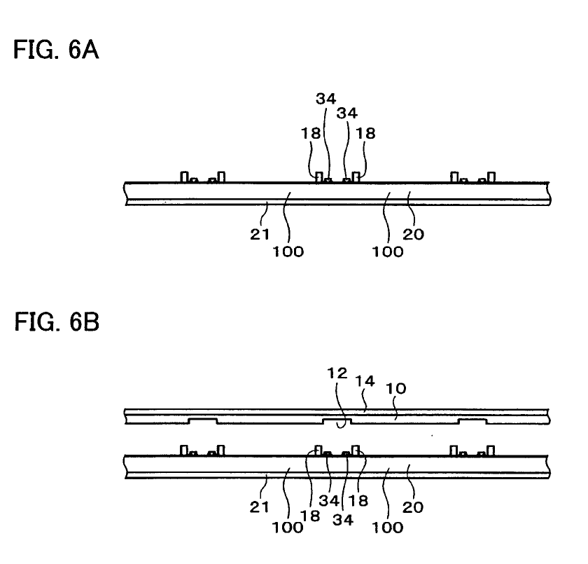

FIGS. 6A and 6B illustrate a second embodiment of the method of manufacturing an optical device according to the present invention. In this embodiment, as shown in FIG. 6A, the spacer 18 is formed on the second substrate 20. If a passivation film is formed on the second substrate 20, the spacer 18 may be formed thereon, or the passivation film may be not formed in the region in which the spacer 18 is formed. The method of forming the spacer 18 is as described in the first embodiment. Then, as shown in FIG. 6B, the first substrate 10 is attached to the spacer 18. With regard to the adhesion between the first substrate 10 and the spacer 18, the observations regarding the adhesion between the second substrate 20 and the spacer 18 described in the first embodiment can be applied. In other respects also, the description of the first embodiment also applies.

Third Embodiment

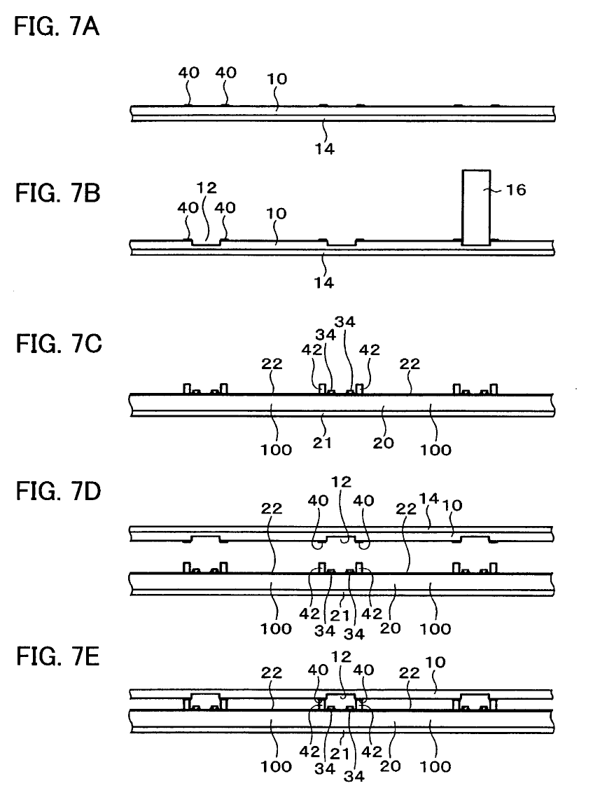

FIGS. 7A to 7E illustrate a third embodiment of the method of manufacturing an optical device according to the present invention. In this embodiment, the first and second substrates 10 and 20 described in the first embodiment are used, but the spacer is formed of a metal. That is to say, a spacer is formed of metal on one of the first and second substrates 10 and 20, and the spacer is attached to the other of the first and second substrates 10 and 20.

As shown in FIG. 7A, on the first substrate 10 a solder material (or seal metal) 40 is provided. The solder material 40 may be either of solder and brazing alloy. The method of providing the solder material 40 may be any of vapor deposition, sputtering, CVD, or plating (for example, electroless plating). If, as in the case of solder paste, the solder material 40 is in paste form, screen printing may be applied. The solder material 40 is provided in the position to be attached to the spacer. In more detail, this is as described in the first embodiment.

As shown in FIG. 7B, the groove 12 is formed in the first substrate 10. The details of this also are as described in the first embodiment. In this embodiment, the groove 12 is formed after providing the solder material 40, but this order may be reversed.

As shown in FIG. 7C, a spacer 42 is formed on the second substrate 20. The spacer 42 is formed of a metal such as nickel or gold. For the method of formation, plating (for example, electroless plating) can be applied.

As shown in FIG. 7D, the first and second substrates 10 and 20 are attached together with the spacer 42 interposed. More concretely, the first substrate 10 is bonded to the spacer 42. For this bonding, soldering or brazing is applied. In more detail, the solder material 40 formed on the first substrate 10 is fused by heating, and the first substrate 10 and spacer 42 are bonded.

As shown in FIG. 7E, when the first and second substrates 10 and 20 have been attached together, thereafter, the process shown in FIGS. 4B and 4C is carried out. In the thus obtained optical device, the optical section 22 is sealed by the transparent substrate 110, spacer 42, and solder material 40.

In respect of other details, the observations described in the first embodiment apply. As a modification of this embodiment, a metal spacer may be provided on the first substrate 10, and this spacer and the second substrate 20 bonded. In this embodiment, soldering or brazing is applied, but instead of providing the solder material, an adhesive may be used.

Fourth Embodiment

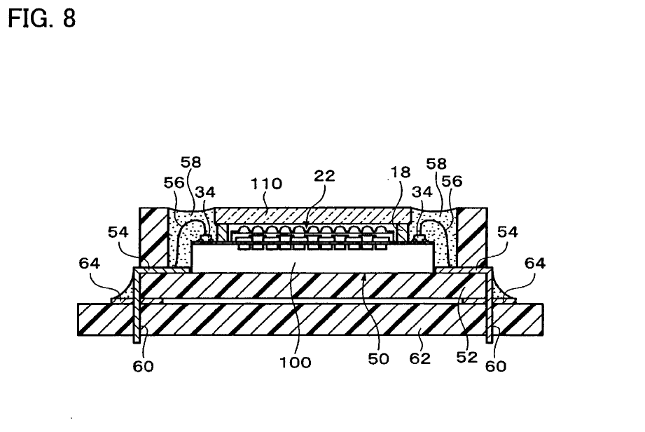

FIG. 8 illustrates a fourth embodiment of an optical module and circuit board according to the present invention. The optical module shown in FIG. 8 has an optical device 50 shown in FIG. 5A. The optical device 50 is attached to a supporting member (for example, a case) 52. On the supporting member 52 interconnecting lines 54 are formed. The supporting member 52 may equally be formed from a member not having the interconnecting lines 54 or the like. The supporting member 52 may be an MID (Molded Interconnect Device). The electrodes 34 of the optical device 50 and the interconnecting lines 54 are electrically connected. For the electrical connections may be used, for example, wires 56. On the electrical connections (for example, wires 56 and bonded portions) a sealing material 58 is provided. That is to say, the electrical connections are sealed by the sealing material 58. The sealing material 58 may be provided, for example, by potting. Since the optical device 50 has the optical section 22 sealed by the transparent substrate 110 and spacer 18, the sealing material 58 does not cover the optical section 22. This is because the transparent substrate 110 and spacer 18 function as a dam with respect to the sealing material 58.

A part of the interconnecting lines 54 forms external terminals (for example, leads) 60. The external terminals 60 are electrically connected to an interconnecting pattern 64 formed on a circuit board 62. In the example shown in FIG. 8, holes are formed in the circuit board 62, and the external terminals 60 are inserted into these holes. Around these holes are formed lands of the interconnecting pattern 64, and these lands and the external terminals 60 are bonded by solder material (for example, solder). In this way the circuit board 62 has the optical module mounted.

Other Embodiments

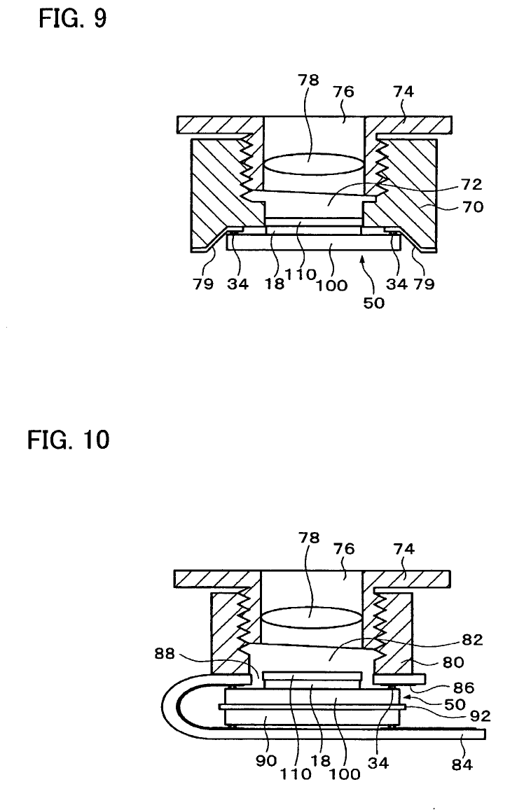

FIG. 9 shows an embodiment of the optical module of the present invention. The optical module shown in FIG. 9 includes the optical device 50 shown in FIG. 5A, and an attached supporting member 70. In the supporting member 70, a hole 72 is formed, and at least a part of the transparent substrate 110 is positioned within the hole 72. In the hole 72 is fitted a lens holder 74. In the lens holder 74 is also formed a hole 76, and within it is fitted a lens 78. The holes 76 and 72 are communicating, and light concentrated by the lens 78 impinges on the first substrate 10. It should be noted that the transparent substrate 110 may be such as to cut light in the infrared region. For the bonding of the electrodes 34 of the optical device 50 and interconnecting lines 79 of the supporting member 70 any of an adhesive, an anisotropic conductive material, an anisotropic conductive film, and metal bonding may be applied. Between the optical device 50 and the supporting member 70 an underfill not shown in the drawings may be provided.

FIG. 10 illustrates an embodiment of the optical module of the present invention. The optical module shown in FIG. 10 includes the optical device 50 shown in FIG. 5A, and an attached supporting member 80. In the supporting member 80 is formed a hole 82, and at least a part of the transparent substrate 110 is positioned within the hole 82. In the hole 82 is fitted a lens holder 74 (details as described above).

In FIG. 10, the optical device 50 is mounted on a substrate 84, and the electrodes 34 and an interconnecting pattern 86 formed on the substrate 84 are bonded. For this bonding, any of an adhesive, an anisotropic conductive material, an anisotropic conductive film, and metal bonding may be applied. Between the optical device 50 and the substrate 84, an underfill not shown in the drawings may be provided. A hole 88 is also formed in the substrate 84. The holes 76, 82, and 88 are communicating, and light concentrated by the lens 78 impinges on the first substrate 10.

On the substrate 84 an electronic component (for example, a semiconductor chip) 90 is mounted (for example, face down mounting). The electronic component 90 and the interconnecting pattern 86 are electrically connected. Additionally, a plurality of electronic components not shown in the drawings may also be mounted. The substrate 84 is bent, and the electronic component 90 and the optical device 50 are adhered with an adhesive 92 interposed. It should be noted that the optical device 50 and electronic component 90 may first be each mounted on the substrate 84, before bending the substrate 84, and adhering the optical device 50 and electronic component 90.

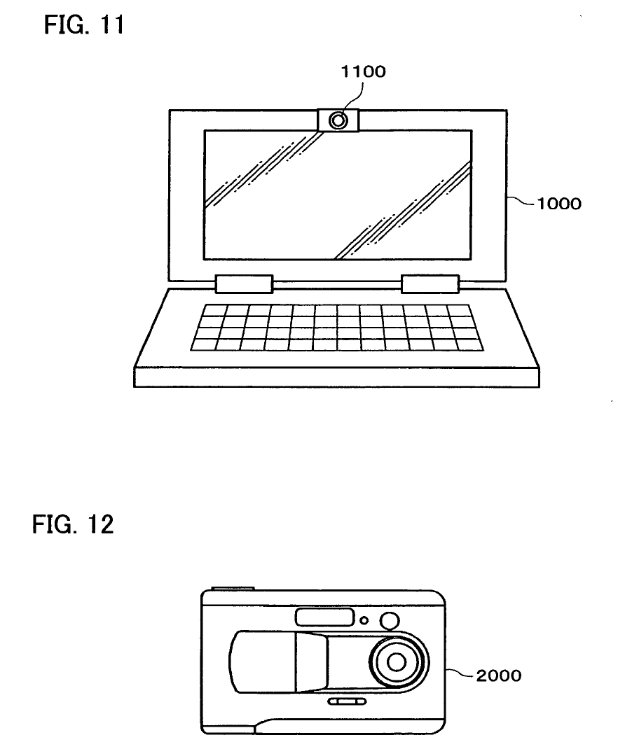

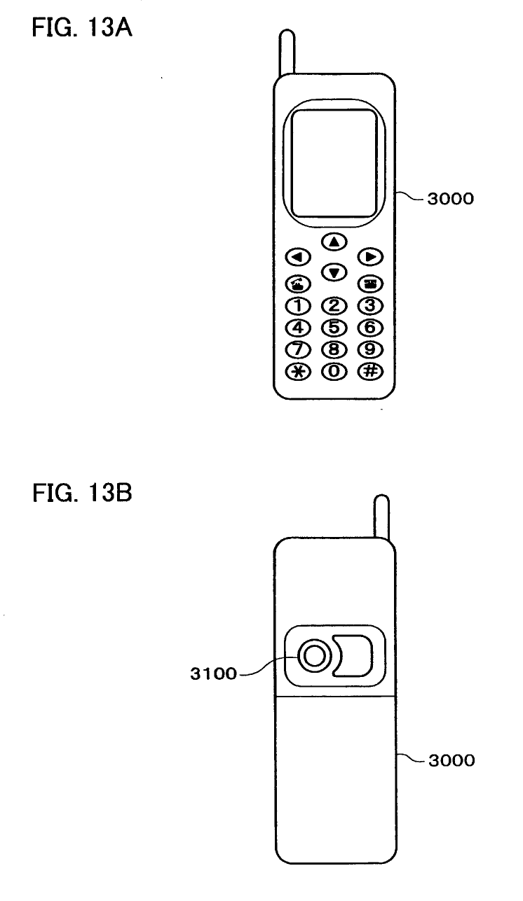

As an embodiment of the electronic instrument of the present invention, a notepad personal computer 1000 shown in FIG. 11 has a camera 1100 in which is incorporated an optical module. A digital camera 2000 shown in FIG. 12 has an optical module. Further, a portable telephone 3000 shown in FIGS. 13A and 13B has a camera 3100 in which is incorporated an optical module.

What is claimed is:

1. A method of manufacturing an optical device comprising:
(a) opposing an optically transmitting first substrate to a second substrate with spacers interposed therebetween, the second substrate including a plurality of optical elements, each of the optical elements having an optical section, each of the spacers surrounding each of the optical sections;
(b) sealing each of the optical sections by the first substrate and the spacers by connecting the first substrate and the second substrate with the spacer interposed; and
(c) separating the second substrate into individual one of the optical elements, the individual one of the optical elements including one of the sealed optical sections.

2. The method of manufacturing an optical device as defined by claim 1,
wherein in the step (c), the first substrate is separated, and
wherein the first substrate is separated with a first cutter, and the second substrate is separated with a second cutter.

3. The method of manufacturing an optical device as defined by claim 2,
wherein a width of the first cutter is greater than a width of the second cutter.

4. The method of manufacturing an optical device as defined by claim 1,
wherein each of the optical elements has electrodes outside of the optical section, and
wherein in the step (c), a part of the first substrate over the electrodes is removed when the first substrate is separated.

5. The method of manufacturing an optical device as defined by claim 3,
wherein the first substrate has a groove formed along a separation line, and
wherein in the step (c), the first substrate is separated in a region in which the groove is formed.

6. The method of manufacturing an optical device as defined by claim 1,
wherein in the step (a), the spacers are formed on one of the first and second substrates, and
wherein in the step (b), the spacers are attached to the other one of the first and second substrates.

7. The method of manufacturing an optical device as defined by claim 1,
wherein each of the spacers has a thermosetting resin, and
wherein the first substrate and the second substrate are connected by heating the spacers in the step (b).

8. The method of manufacturing an optical device as defined by claim 1,
wherein each of the spacers has a light curable resin, and
wherein the first substrate and the second substrate are connected by irradiating the spacers with light in the step (b).

9. The method of manufacturing an optical device as defined by claim 7,
wherein the thermosetting resin is provisionally cured before the step (b).

10. The method of manufacturing an optical device as defined by claim 8,
wherein the light curable resin is provisionally cured before the step (b).

11. The method of manufacturing an optical device as defined by claim 6,
wherein the spacers are formed of metal, and
wherein in the step (b), soldering or brazing is carried out.

12. The method of manufacturing an optical device as defined by claim 11,
wherein a solder or a brazing alloy is provided on one of the first and second substrates to which the spacers are to be attached, before carrying out the soldering or brazing.

13. The method of manufacturing an optical device as defined by claim 1,
wherein in the step (b), the optical section is sealed so as to form a space between the first substrate and the optical section.

14. The method of manufacturing an optical device as defined by claim 13,
wherein in the step (b), the optical section is sealed so that the space is vaccumized.

15. The method of manufacturing an optical device as defined by claim 13,
wherein in the step (b), the optical section is sealed so that the space is filled with nitrogen.

16. The method of manufacturing an optical device as defined by claim 13,
wherein in the step (b), the optical section is sealed so that the space is filled with dry air.

17. The method of manufacturing an optical device as defined by claim 1,
wherein the first substrate transmits visible light, and does not transmit infrared radiation.

18. The method of manufacturing an optical device as defined by claim 1,
wherein the second substrate is a semiconductor wafer.

19. The method of manufacturing an optical device as defined by claim 1,
wherein each of the optical sections has a plurality of photoreceptors arranged for image sensing.

20. The method of manufacturing an optical device as defined by claim 1,
wherein each of the optical sections has a color filter provided over the photoreceptor.

21. The method of manufacturing an optical device as defined by claim 1,
wherein each of the optical sections has a microlens array provided on the surface of the second substrate.

22. An optical device manufactured by the method as defined by claim 1.

23. An optical module comprising:
the optical device as defined by claim 22; and
a supporting member to which the optical device is attached.

24. A circuit board on which the optical module as defined by claim 23 is mounted.

25. An electronic instrument comprising the optical module as defined by claim 23.
